(19) United States
(12) Patent Application Publication
(10) Pub. No.: US 2002/0104994 A1
(43) Pub. Date: Aug. 8, 2002

(54) Method of manufacturing thin film transistor

(76) Inventor: Po-Sheng Shih, Hsinchu (TW)

Correspondence Address: J.C. Patents, Inc., Suite 250, 4 Venture, Irvine, CA, 92618, US

(21) Appl. No.: 09/930,847

(22) Filed: Aug. 14, 2001

(30) Foreign Application Priority Data
Feb. 6, 2001 (TW) 90102493

(51) Int. Cl. H01L 29/76

(52) U.S. Cl. 257/66

(57) ABSTRACT

A thin film transistor. The thin film transistor has an ultra thin polysilicon layer over a substrate, a gate structure that includes a gate layer, a gate oxide layer between the gate layer and the ultra thin polysilicon layer and a spacer on each sidewall of the gate layer, and a conductive layer over the ultra thin polysilicon layer and the gate layer adjacent to the spacers. A selective deposition, such as an in-situ silicon-germanium deposition that utilizes the difference in properties between the spacer and silicon, is conducted to form the conductive layer.

### CROSS-REFERENCE TO RELATED APPLICATION

This application claims the priority benefit of Taiwan application Ser. No. 90102493, filed Feb. 6, 2001.

### BACKGROUND OF THE INVENTION

1. Field of Invention

The present invention relates to a type of thin film transistor. More particularly, the present invention relates to an ultra thin channel thin film transistor that can be used in a display device.

2. Description of Related Art

Image display devices are indispensable in our daily life. All our televisions and computer systems must at least include a display device for displaying images. In general, a cathode ray tube tends to occupy lots of space leading to great inconveniences. Due to large volume occupation, using a cathode ray tube in a notebook computer is infeasible. Recently, planar display products with a dot matrix design, such as a thin film transistor liquid crystal display (TFT LCD), have been successfully incorporated into notebook computers and other desktop computers.

A number of thin film transistor designs are available. Principally, the channel of a thin film transistor is constructed using polysilicon. A type of thin film transistor known as an ultra thin channel thin film transistor has a very thin channel. The ultra thin channel has a relatively small thickness of only between 200 Å to 500 Å compared with a conventional thin film transistor.

FIGS. 1A and 1B are schematic cross-sectional views showing the steps for forming a conventional ultra thin channel thin film transistor. As shown in FIG. 1A, a substrate 100 having a polysilicon pad layer 102 thereon is provided. The polysilicon pad layer 102 is destined to be the source/drain terminal of the thin film transistor. In general, the polysilicon pad layer 102 requires an ion implantation and an annealing process. An ultra thin polysilicon layer 104 is formed on the upper surface and sidewalls of the polysilicon pad layer 102. The ultra thin polysilicon layer 104 also covers the upper surface of the substrate 100 between neighboring polysilicon pad layers 102. The polysilicon pad layer has a thickness of about 1000 Å while the ultra thin polysilicon layer 104 has a thickness of just 300 Å.

As shown in FIG. 1B, an oxide layer and a polysilicon layer are sequentially formed over the ultra thin polysilicon layer 104. The oxide layer and the polysilicon are patterned to form a gate structure that includes a gate oxide layer 106 and a polysilicon gate layer 108. The polysilicon pad layer 102 and the ultra thin polysilicon layer 104 together constitute the source/drain terminals of a thin film transistor.

In the aforementioned method of forming the thin film transistor, one more photolithographic and etching process is conducted to pattern the polysilicon pad layer 102. Moreover, the gate structure may not align accurately with the underlying pattern layer.

The ultra thin channel thin film transistor design has a few advantages. For example, an ultra thin channel thin film transistor has a lower threshold voltage, smaller leakage current and higher carrier mobility. However, a larger source/drain terminal resistance often reduces ‘On’ current. Therefore, decreasing the source/drain resistance is a major issue for a conventional ultra thin channel transistor. Moreover, the conventional manufacturing method is a complicated and non-self-aligned process.

### SUMMARY OF THE INVENTION

Accordingly, one object of the present invention is to provide an ultra thin channel thin film transistor structure capable of lowering source/drain resistance and simplifying the production process. Moreover, no additional photolithographic and etching process is required to pattern a polysilicon pad layer, and misalignment of the gate structure during patterning is avoided.

To achieve these and other advantages and in accordance with the purpose of the invention, as embodied and broadly described herein, the invention provides a thin film transistor structure. The thin film transistor includes an ultra thin polysilicon layer over a substrate and a gate structure over the polysilicon layer. The gate structure includes a gate layer, a gate oxide layer between the gate layer and the ultra thin polysilicon layer and a spacer on each sidewall of the gate layer. A conductive layer is above the ultra thin polysilicon layer and the gate layer adjacent to the spacers.

This invention also provides a method of forming a thin film transistor. An insulating substrate is provided. A polysilicon layer is formed over the substrate and then a gate structure is formed over the polysilicon layer. The gate structure includes a gate layer, a gate dielectric layer between the gate layer and the polysilicon layer and a spacer on each sidewall of the gate layer. Finally, a conductive layer is formed over the gate layer and the polysilicon layer.

The polysilicon layer has a thickness between about 200 Å to 500 Å. Furthermore, a special selective mechanism between the spacer and silicon material is utilized to form the conductive layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A and 1B are schematic cross-sectional views showing the steps for forming a conventional ultra thin channel thin film transistor; and

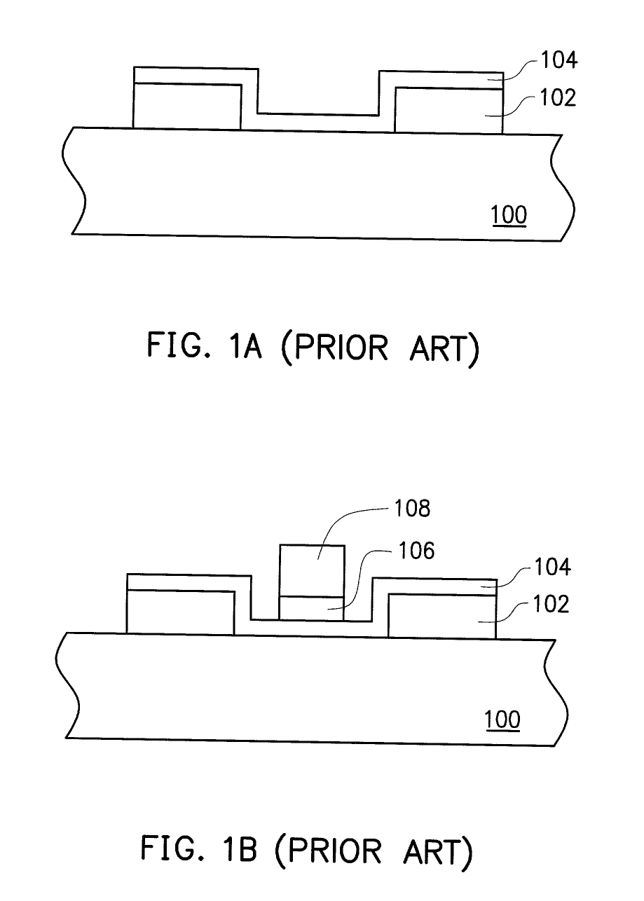

FIGS. 2A through 2C are schematic cross-sectional views showing the progression of steps for forming an ultra thin channel thin film transistor according to this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

One major aspect in the invention is the utilization of a selective deposition mechanism in the fabrication of a source/drain terminal of a thin film transistor. The deposition is a self-aligned process capable of reducing one masking step. In addition, the conductive pad layer above the source/drain terminal can be a silicon-germanium (SiGe) layer formed by in-situ doping. Therefore, one doping and annealing step is saved.

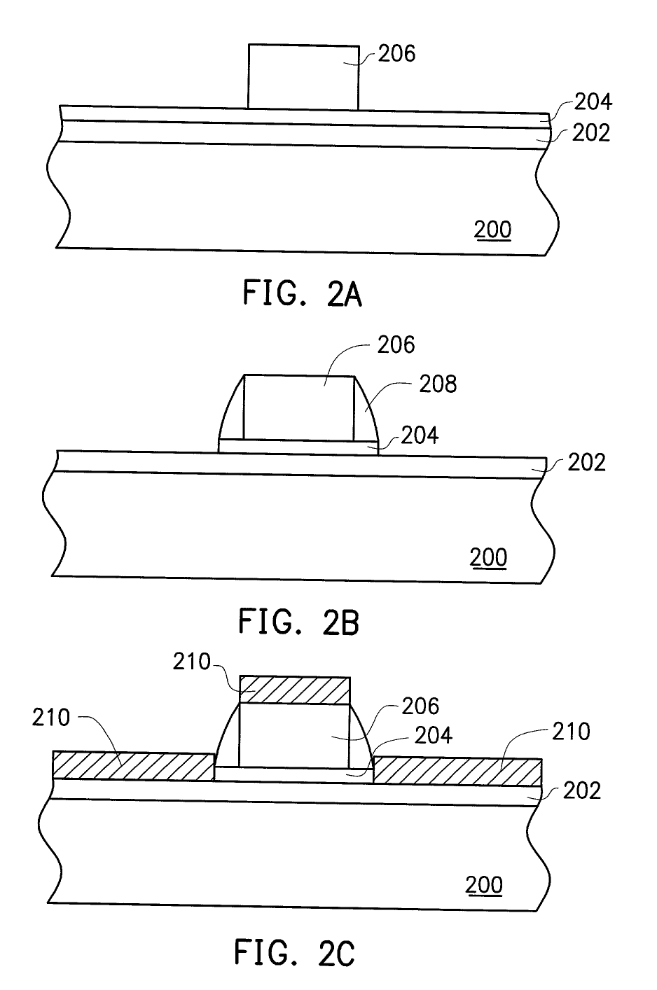

FIGS. 2A through 2C are schematic cross-sectional views showing the progression of steps for forming an ultra thin channel thin film transistor according to this invention.

As shown in FIG. 2A, an insulating substrate 200 is provided. A polysilicon layer 202 is formed over the substrate 200. The polysilicon layer 202 has a thickness of between 200 Å to 500 Å and preferably between 250 Å to 350 Å, which is smaller than a conventional channel layer having a thickness of about 500 Å. The polysilicon layer 202 subsequently serves as a channel layer. A dielectric layer 204 is formed over the polysilicon layer 202. A polysilicon gate layer 206 is formed over the dielectric layer 204. The polysilicon gate layer 206 can be formed, for example, by an in-situ doping.

As shown in FIG. 2B, a spacer 208 is formed on each sidewall of the gate layer 206. The spacers 208 are formed by depositing dielectric material to cover the gate layer 206, and then etching back the dielectric layer. Using the gate layer 206 and the spacers 208 as a mask, the dielectric layer 204 is etched to expose a portion of the polysilicon layer 202. The dielectric layer 204 underneath the gate layer 206 and the spacers 208 is a gate dielectric layer such as a gate oxide layer. The spacers 208 are preferably made using tetra-ethyl-ortho-silicate (TEOS) material. Spacer material is selected according to considerations such as selectivity during deposition, especially the difference in the depositing rate relative to silicon material. In general, dielectric material, such as oxide and nitride, has suitable selectivity in the aforementioned deposition process.

Up to the present stage, a gate structure that includes a gate oxide layer 204, a gate layer 206 and sidewall spacers 208 is formed over the polysilicon layer 202. The component layers 204, 206 and 208 can be formed by other conventional means as well. For example, the dielectric layer 204 may be etched before forming the spacers 208. However, the spacers 208 are preferably formed using TEOS material.

As shown in FIG. 2C, the polysilicon layer 202 is specially formed over the substrate 200. After forming the gate structure, the polysilicon layer 202 on each side of the gate structure is exposed. The surface of the spacer 208 and the surface of the gate layer 206 and the silicon surface of the polysilicon layer 202 together form pairs of contrasting surfaces. For some materials, these contrasting surfaces provide a mechanism for selective deposition. For example, silicon-germanium (SiGe) material is deposited only over a silicon surface by chemical vapor deposition (CVD). During a SiGe deposition, dopants may be added into the deposited layer in-situ. Ultimately, there is no need to set up another ion implantation or a subsequent annealing step. In addition, there is no need to perform a photolithographic process after SiGe deposition because SiGe material will automatically deposit over the exposed polysilicon layer 202 and the gate layer 202 to form a conductive layer 210. In other words, the SiGe deposition is a self-aligned process. Aside from SiGe material, tungsten or other metal may also utilize the selective deposition mechanism to form a conductive layer. The conductive layer 210 serves as the source/drain terminal of a thin film transistor. The thickness of the conductive layer 210 can reduce the resistance at the source/drain terminal of the ultra thin polysilicon layer.

Furthermore, if the selective deposition mechanism is not used, other self-aligned silicide processes can be used so that a metal silicide layer is formed. A self-aligned silicide process is carried out by depositing a refractory metal and then performing a thermal treatment so that the refractory metal reacts with silicon in the silicon layer to form a silicide layer. Thereafter, the unreacted metal is removed.

When the conductive layer 210 is formed, some conductive material may also be deposited over the spacers 208. An etching step may be added to remove this conductive material from the spacers. However, since the amount of conductive material over the spacers 208 is small, the conductive layer 210 will not be damaged by the etching process. In conclusion, some major features provided by the invention include:

1. The conductive layer that constitutes the source/drain terminals of the thin film transistor is formed by selective deposition. Hence, one masking step is eliminated.

2. The conductive layer may be formed by a self-aligned silicon process as well.

3. In-situ doping is performed when the SiGe source/drain terminal is formed. Hence, direction implantation followed by an annealing treatment is unnecessary.

4. The SiGe source/drain terminal has a lower resistance than a conventional ultra thin channel thin film transistor.

5. All the steps required to form the ultra thin channel are carried out at a relatively low temperature so that the overall thermal budget of the fabrication is greatly reduced.

6. No masking step is required to form thick conductive source/drain terminals. Hence, resistance at the source/drain terminal of the ultra thin polysilicon layer is reduced.

7. The spacers are formed using TEOS material so that sufficient selectivity is provided in a SiGe deposition.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a thin film transistor, comprising the steps of:
providing an insulating substrate;
forming a polysilicon layer over the substrate;
forming a gate structure over the polysilicon layer, wherein the gate structure includes a gate layer, a gate dielectric layer between the gate layer and the polysilicon layer and a spacer on each sidewall of the gate layer; and
forming a conductive layer over the gate layer and the polysilicon layer.

2. The method of claim 1, wherein the polysilicon layer has a thickness between about 200 Å to 500 Å.

3. The method of claim 1, wherein the step of forming the conductive layer includes performing a selective deposition according to a selective deposition mechanism due to differences in material properties between the spacer and the polysilicon layer.

4. The method of claim 3, wherein the conductive layer includes an in-situ doped silicon-germanium (SiGe) layer.

5. The method of claim 3, wherein the conductive layer includes a tungsten layer.

6. The method of claim 3, wherein the step of forming the conductive layer includes forming a metal suicide layer by conducting a self-aligned silicide process.

7. The method of claim 3, wherein the step of forming the spacers includes depositing tetra-ethyl-ortho-silicate (TEOS).

8. The method of claim 1, wherein the gate layer includes a polysilicon layer.

9. The method of claim 1, wherein the gate layer includes an in-situ doped polysilicon layer.

10. A method of forming a thin film transistor, comprising the steps of:
providing an insulating substrate;
forming an ultra thin conductive layer over the substrate;
forming a gate structure over the ultra thin conductive layer, wherein the gate structure includes a gate layer, a gate dielectric layer between the gate layer and the ultra thin conductive layer and a spacer on each sidewall of the gate layer; and
forming a conductive layer over the gate layer and the ultra thin conductive layer, wherein a portion of the conductive layer is a source/drain terminal of the thin film transistor.

11. The method of claim 10, wherein the ultra thin conductive layer includes an in-situ doped silicon-germanium (SiGe) layer.

12. The method of claim 10, wherein the ultra thin conductive layer has a thickness between about 200 Å to 500 Å.

13. The method of claim 10, wherein the step of forming the conductive layer includes performing a selective deposition according to a selective deposition mechanism due to differences in material properties between the spacer and the polysilicon layer.

14. The method of claim 10, wherein the conductive layer includes an in-situ doped silicon-germanium (SiGe) layer.

15. A thin film transistor structure, comprising:
an insulating substrate;
a polysilicon layer over the substrate;
a gate structure over the polysilicon layer, wherein the gate structure includes a gate layer, a gate dielectric layer between the gate layer and the polysilicon layer and a spacer on each side of the gate layer; and
a conductive layer over the gate layer and the polysilicon layer adjacent to the spacers.

16. The structure of claim 15, wherein the polysilicon layer has a thickness between about 250 Å to 350 Å.

17. The structure of claim 15, wherein the conductive layer includes an in-situ doped silicon-germanium (SiGe) layer.

18. The structure of claim 15, wherein the conductive layer includes a tungsten layer.

19. The structure of claim 15, wherein the conductive layer includes a metal silicide layer.

20. The structure of claim 15, wherein the spacer includes a tetra-ethyl-ortho-silicate (TEOS) layer.
